(19) United States
(12) Patent Application Publication
(10) Pub. No.: US 2002/0167044 A1
(43) Pub. Date: Nov. 14, 2002

(54) Semiconductor component with an edge termination that is suitable for high voltage

(76) Inventor: Hans Weber, Ainring (DE)

Correspondence Address: LERNER AND GREENBERG, P.A., Post Office Box 2480, Hollywood, FL, 33022-2480, US

(21) Appl. No.: 10/144,223

(22) Filed: May 13, 2002

(30) Foreign Application Priority Data
May 11, 2001 (DE) 101 22 846.5

(51) Int. Cl. H01L 29/76

(52) U.S. Cl. 257/328

(57) ABSTRACT

The semiconductor component has a source connecting region, a drain connecting region, and a gate connection region for connection of a semiconductor switching element. An edge termination region in this case provides an edge termination that is suitable for high voltages. The gate connecting region is at least partially located in the edge termination region which is suitable for high voltage. This results in an increase in the surface area for the active cell array, and hence in better value, without detracting from the electrical characteristics of the edge termination.

### BACKGROUND OF THE INVENTION

### Field of the Invention

The invention lies in the semiconductor technology field. More specifically, the present invention relates to a semiconductor component with an edge termination that is suitable for high voltage, and in particular to a compensation component as is known as a CoolMOS™ module.

In vertical power transistors, the voltage in the active chip region (=cell array) between the source and drain is reduced continuously in the vertical direction in the volume of the semiconductor substrate, that is to say from the front face toward the rear face.

Close to the chip edges (that is to say well outside the cell array), crystal faults occur in the semiconductor volume, which are a result of the process of separating the chips (for example sawing from the wafer assembly). Since these crystal faults can be regarded as generation centers for charge carriers, there must be no electrical field there (which would otherwise lead to a severe undesirable blocking current). This is one of the reasons why a drain potential is “pulled up” at the chip edge toward the front face of the chip (while it is located on the rear face of the chip for the cell array, as is characteristic of a vertical component). This means that, starting from the cell array, the source-drain voltage decreases laterally toward the edge, and the outer boundaries of the chip are at a constant voltage (namely the drain potential), that is to say there is no field. The deliberate raising of the potential lines that is achieved toward the surface is often achieved with the aid of equipotential plates.

The critical factor for the forming of the field lines is a source potential plate (and possibly further field plates, which are at a constant potential between the source potential and drain potential). These plates are normally conductive layers (often composed of metal or highly conductive polysilicon).

The source potential plate is coupled, for example, to the source connection in the cell array. Starting from the cell array toward the chip edge, the vertical distance between the field plate and the semiconductor substrate is increased in steps, so that the potential lines are guided from the semiconductor volume toward the surface (the potential lines are approximately equidistant from one another in the semiconductor substrate; since the source potential line matches the field plate which has been mentioned and is drawn upward, all the other potential lines thus behave in the same way; the potential line profiles are thus formed in a similar way to that for a capacitor).

Since the more deeply located semiconductor volume is also acceptable in compensation components, in contrast to conventional components, a different effect can also be used here to form the potential lines:

The profile of the potential lines can be changed to any desired curved shape at the chip edge by variation of the charge balance (that is to say the compensation conditions)—seen in the lateral direction—(in the process, all that need be remembered is that this measure does not result in any “early breakdown” being produced, owing to excessive potential field compression). This option is used normally for the purpose of deliberately pulling up all the field lines toward the surface. The effect can, of course, be coupled to field plates used on the surface.

On the surface, the potential lines enter oxide layers which are used, for example, to appropriately predetermine the vertical distance between the field plate and the semiconductor substrate. Finally, when the drain potential line enters this surface oxide, the potential in the semiconductor volume/chip edge is completely dissipated (in the lateral direction), that is to say the drain potential is the predominant factor at the outer chip edges on the surface.

In order to reduce this voltage towards the edge of the semiconductor body, or toward the chip edge, so-called edge terminations which are suitable for high voltage must in consequence be formed. They allow the voltage to be reduced in a defined manner on the surface of the semiconductor body, toward its edge.

Particularly in the case of power semiconductor components, there are thus various edge regions which do not carry current, that is to say which are inactive, and which, although they are essential for the operation of the component, are generally underestimated in terms of their value.

FIG. 1 shows a simplified plan view of a semiconductor component with an edge termination that is suitable for high voltage, according to the prior art. The reference ZB denotes an active region or an actually active cell array, wherein the actual active semiconductor switching elements are located. A source connecting region SP is normally arranged immediately above the cell array ZB. A respective source is connected via the source connecting region SP, and it is also often used as a so-called source pad (bonding on active regions) for space optimization. A control layer or a gate is, furthermore required for actuation of the semiconductor switching elements formed in the cell array, and is normally connected within the source connecting region SP to a gate connecting region GP. The gate connecting region GP is in this case used as a so-called gate pad for connection or bonding to an external circuit. As shown in FIG. 1, there is a so-called edge termination region RB located at the chip edge, in order to provide an edge termination which is suitable for high voltage.

In this edge termination region RB, a voltage which is blocked in the vertical direction in the cell array ZB is dissipated laterally toward the chip edge. Field plate structures positioned on the surface are (often) used for this purpose, giving the equipotential lines a defined profile and leading from the semiconductor volume to a predetermined insulating layer structure. There, owing to the very high breakdown field strengths of, for example, oxide as the insulating layer, the potential lines are then compressed, which corresponds to an increase in the field, without this leading to early breakdown. The outlet area of the potential lines is thus deliberately minimized in the edge termination region RB.

According to FIG. 1, the inner potential plate, facing the cell array ZB, of the edge termination region RB is normally at the source potential, and corresponds to the source connecting region SP, while an outer potential plate, or an electrically conductive ring arranged at the chip edge, normally represents a drain potential plate DP.

### SUMMARY OF THE INVENTION

It is accordingly an object of the invention to provide a semiconductor component with high-voltage proof edge termination, which overcomes the above-mentioned disadvantages of the heretofore-known devices and methods of this general type and which achieves better value in production.

With the foregoing and other objects in view there is provided, in accordance with the invention, a semiconductor component, comprising:

a source connecting region, a drain connecting region, and a gate connection region for connection of a semiconductor component; and

an edge termination region for providing an edge termination suitable for high voltage;

wherein the gate connecting region is at least partially located in the edge termination region suitable for high voltage.

In accordance with an added feature of the invention, the gate connecting region at least partially surrounds the source connecting region in the form of an annulus.

In accordance with an additional feature of the invention, the edge termination region has an outer potential plate and an inner potential plate, and the inner potential plate faces the cell array and is at least partially at gate potential.

In accordance with another feature of the invention, the edge termination region has a first insulating layer, a first electrically conductive layer a second insulating layer, and a second electrically conductive layer, the first and second electrically conductive layers are at least partially connected to one another in an outer region and an inner region of the edge termination region.

In accordance with a concomitant feature of the invention, the semiconductor component is a semiconductor switching element with a cell array and has a charge compensation structure in the cell array.

Particularly as a result of the arrangement of the gate connection region at least partially in the edge termination region, it is possible to shift an associated inactive region, which is relevant in terms of area, into the likewise inactive outer edge termination region, so that the electrical characteristics of the semiconductor component remain essentially unchanged, while achieving a considerable gain of surface area for the active region and the cell array.

The gate connecting region is preferably at least partially annular in shape and surrounds the source connecting region, thus achieving particularly good connection characteristics, in particular for the control layer and the gate.

The edge termination region preferably has an outer and an inner potential plate, with the inner potential plate being at least partially at the gate potential. In this case, the gate is used as part of the edge termination, essentially resulting in no deterioration in the characteristics of the edge termination, since the gate potential generally corresponds essentially to a source potential.

Other features which are considered as characteristic for the invention are set forth in the appended claims.

Although the invention is illustrated and described herein as embodied in a semiconductor component with an edge termination which is suitable for high voltage, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a simplified plan view of a semiconductor component with an edge termination that is suitable for high voltage, according to the prior art;

FIG. 2 is a simplified plan view of a semiconductor component with an edge termination that is suitable for high voltage, according to a first exemplary embodiment of the invention;

FIG. 3 is a simplified plan view of a semiconductor component with an edge termination that is suitable for high voltage, according to a second exemplary embodiment of the invention;

FIG. 4 is a simplified section taken along the line IV-IV shown in FIGS. 2 and 3;

FIG. 5 is a simplified section taken along the line V-V shown in FIGS. 2 and 3; and

FIG. 6 is a simplified section taken along the line VI-VI shown in FIGS. 2 and 3.

### DESCRIPTION OF THE PREFERRED EMBODIMENTS

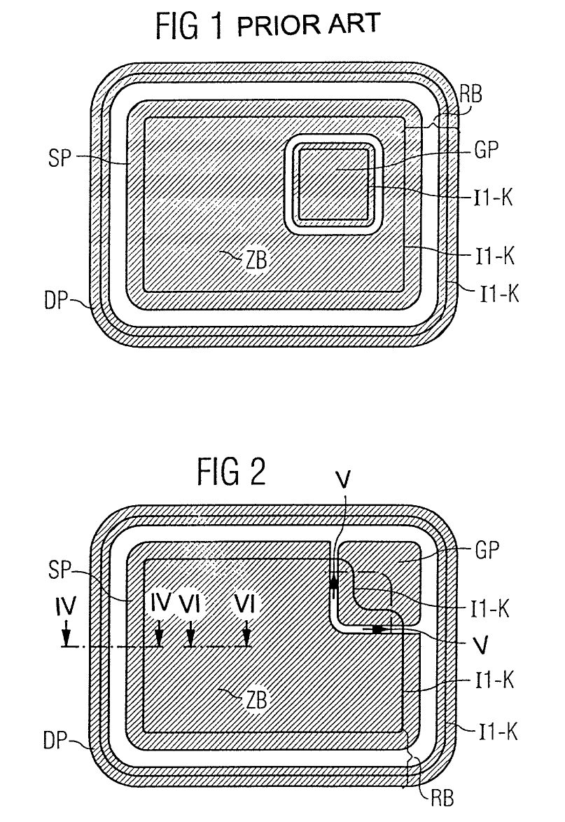

Referring now once more to the figures of the drawing in detail and, particularly, to FIG. 2 thereof, there is shown a simplified plan view of a semiconductor component with an edge termination that is suitable for high voltage, according to a first exemplary embodiment of the invention. The same or functionally equivalent layers or elements are identified with identical reference symbols as in FIG. 1, and they will not be described again in the following text.

According to FIG. 2, the gate connecting region or the gate pad GP is shifted into the edge termination region RB such that it is located entirely outside the cell array ZB and the source connecting region SP. In consequence, the inactive region underneath the gate connecting region GP, or at least a part of it, is shifted into the inactive region of the edge termination region RB, thus resulting in a considerable reduction in the inactive areas in the semiconductor component. Particularly in the case of semiconductor components with small surface dimensions, this results in an advantageous gain in surface area for the active region and the cell array ZB, thus considerably improving the value per semiconductor module or chip.

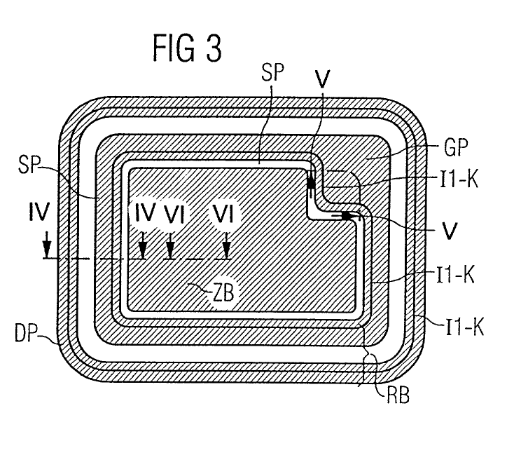

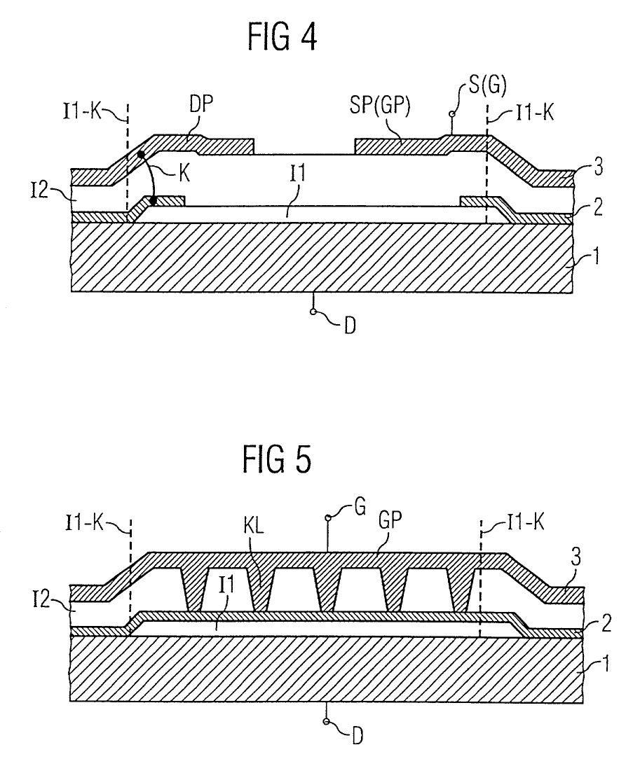

FIG. 4 shows a simplified section view of the edge termination region RB along a section IV-IV as shown in FIG. 2 and in FIG. 3, with the same reference symbols once again denoting the same or corresponding elements.

According to FIG. 4, the semiconductor component with an edge termination which is suitable for high voltage has a semiconductor substrate 1, which preferably comprises a silicon semiconductor substrate or a large number of epitaxially deposited semiconductor layers. The drain connecting region is in this case located on the lower face of the semiconductor substrate 1, and is connected to a drain electrode D. A gate insulation layer, which is not illustrated but is composed, for example, of thermally formed silicon dioxide, is normally formed on the surface of the semiconductor substrate 1. A first insulating layer I1 is, furthermore, formed between an outer edge and the inner cell array ZB in the region of the edge termination region RB, and is preferably composed of a thick oxide layer (first oxide). An electrically conductive layer 2 is formed on the surface of this first insulating layer I1 and/or on the semiconductor substrate 1, is preferably composed of highly doped polysilicon and, in order to avoid electrical contact between the chip outer edge and the cell array region ZB, is structured or interrupted in the region above the first insulating layer I1.

A second insulating layer I2 is then formed, which is referred to as a so-called intermediate oxide and is preferably once again composed of silicon dioxide. A second electrically conductive layer 3 is formed on the surface of this second insulating layer I2 and is structured such that there is once again no electrical contact between the chip edge and the cell array ZB. The second electrically conductive layer I2 consists, for example, of metallic material, and is preferably composed of aluminum.

According to FIGS. 2 and 4, the inner region of the edge termination region RB is thus formed from an inner potential plate, which corresponds to the source connecting region SP, and an outer potential plate DP, which is electrically connected to the first conductive layer 2, which is located underneath and faces the chip edge, via a contact K which is normally formed by the conductive edge of the chip edge. Since it is also connected to the drain connecting region via the chip edge, it is also referred to as a drain potential plate DP.

An adequate edge termination for defined potential dissipation along a chip edge is thus produced in the edge termination region RB illustrated in FIG. 4. According to FIG. 4, the reference symbol I1-K furthermore denotes an edge between the first insulating layer I1 and the gate insulation layer, which is not illustrated but is located immediately under the first electrically conductive layer 2. This edge I1-K essentially defines the edge termination region RB.

FIG. 5 shows a simplified section view along a section V-V as shown in FIG. 2, with identical reference symbols once again denoting the same or similar layers as in FIG. 2 or 4, which will not be described again in the following text.

In consequence, according to FIG. 5, the layer structure in the gate connecting region GP corresponds essentially to the layer structure in the edge termination region RB so that the gate connecting region can be shifted into the edge termination region RB. In order to make contact with the electrically conductive second layer 2 which represents the control layer, a large number of contact holes KL are formed, for example, in the gate connecting region GP in the second insulating layer I2, so that the second electrically conductive layer 3 makes direct contact with the first electrically conductive layer 2.

While the section V-V illustrated in FIG. 5 essentially relates to the cell array ZB, the outer region of the gate connecting region GP may essentially have the same layer view as is shown in FIG. 4. This results in better value, owing to the advantageous gain in surface area for the active region or the cell array ZB, without significantly influencing the electrical characteristics of the edge termination region RB.

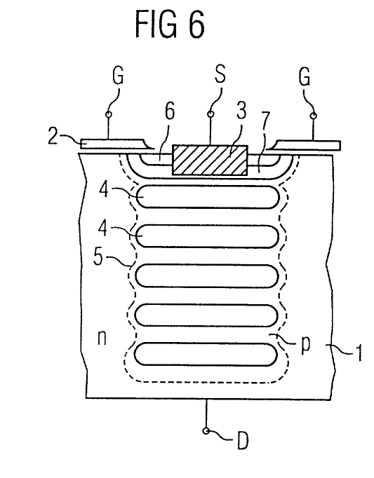

FIG. 6 shows a simplified section view along a section VI-VI in the cell array ZB shown in FIG. 2, with identical reference symbols once again denoting the same or corresponding layers and elements, which will not be described once again in the following text.

According to FIG. 6, the semiconductor component, as a power semiconductor switching element, has a structure with lateral charge compensation. Such charge compensation structures, which are preferably used in compensation components, have a reverse-biased pn-junction in the semiconductor substrate 1, with a first zone 6 of a first conductance type, which is connected to the second electrically conductive layer 3 and to a source electrode S, and which is adjacent to a zone 7, which forms the reverse-biased pn-junction, of a second conductance type, which is the opposite to the first conductance type, and this is likewise connected to the source electrode S. A second zone of the first conductance type is connected in the lower region of the semiconductor substrate 1 to the drain electrode D, with first and second compensation regions being interleaved in one another in the region between the first zone 7 and the second zone. The first compensation regions are in this case essentially formed from the intermediate regions, formed in the semiconductor substrate 1, of the second compensation regions 5.

The second compensation regions 5 are preferably formed from a large number of compensation zones 4 which are formed, for example, by a large number of epitaxial layers in the semiconductor substrate 1. This results in a semiconductor component to whose cell array particularly high voltages can be applied, and which has particularly high breakdown voltages in its edge region.

FIG. 3 shows a simplified plan view of a semiconductor component with an edge termination which is suitable for high voltage, according to a second exemplary embodiment, with identical reference symbols once again denoting the same or corresponding layers, which will not be described once again in the following text.

According to FIG. 3, the gate connecting region GP now comprises an annular region, which completely surrounds the source connecting region SP and thus acts as an inner potential plate for the edge termination region RB. In order to provide a sufficiently large area for bonding, the gate connecting region is broadened, as shown in FIG. 3 (in the upper right-hand corner section).

The section views shown in FIGS. 4 to 6 along the sections IV-IV, V-V, and VI-VI in this case once again correspond essentially to the section views illustrated in FIGS. 4 to 6, and they will therefore not be described in detail in the following text.

In consequence, according to FIG. 3, the inner potential plate, facing the cell array ZB, of the edge termination region RB is entirely at the gate potential, since it corresponds to the gate connecting region GP. Since the edge structure or the edge termination once again essentially has the same construction as an inner region of the gate connecting region, this results in essentially unchanged electrical characteristics for the edge termination RB. In particular, in the case of the arrangement illustrated in FIG. 3, the electrical characteristics of the semiconductor component are also improved, since a respective contact with the first electrically conductive layer 2 (control layer), which is normally composed of relatively poorly conductive polysilicon, is optimum at any point in the cell array ZB.

Alternatively, in addition to the exemplary embodiments illustrated in FIGS. 2 and 3, a gate connecting region GP can also be configured such that it only partially surrounds the source connecting region SP in an annular shape. In this case, only parts of the inner potential plate are at the gate potential.

The term “high voltage” as used herein is to be understood to refer to voltages above 100 V. The novel semiconductor component is particularly suitable for voltages above 500 V.

The invention has been described above with reference to a power semiconductor component with a charge compensation structure. However, it is not restricted to this and, in the same way, also covers other semiconductor components with an edge termination that is suitable for high voltage.

I claim:

1. A semiconductor component, comprising:
a source connecting region, a drain connecting region, and a gate connection region for connection of a semiconductor component; and
an edge termination region for providing an edge termination suitable for high voltage;
wherein said gate connecting region is at least partially located in said edge termination region suitable for high voltage.

2. The semiconductor component according to claim 1, wherein said gate connecting region at least partially surrounds said source connecting region annularly.

3. The semiconductor component according to claim 1, which comprises a cell array, and wherein said edge termination region has an outer potential plate and an inner potential plate, and said inner potential plate faces said cell array and is at least partially at gate potential.

4. The semiconductor component according to claim 1, wherein said edge termination region has a first insulating layer, a first electrically conductive layer a second insulating layer, and a second electrically conductive layer, said first and second electrically conductive layers are at least partially connected to one another in an outer region and an inner region of said edge termination region.

5. The semiconductor component according to claim 1 forming a semiconductor switching element with a cell array and having a charge compensation structure in said cell array.
